(19) United States
(12) Patent Application Publication
(10) Pub. No.: US 2024/0290922 A1
(43) Pub. Date: Aug. 29, 2024

(54) SEMICONDUCTOR DEVICE AND DISPLAY DEVICE

(71) Applicant: SONY GROUP CORPORATION, TOKYO (JP)

(72) Inventor: KEIJI SUGI, TOKYO (JP)

(21) Appl. No.: 18/572,437

(22) PCT Filed: Mar. 11, 2022
(86) PCT No.: PCT/JP2022/010767

§ 371 Date: Dec. 20, 2023

(30) Foreign Application Priority Data
Jun. 28, 2021 (JP) 2021-106921

(51) Int. Cl. H01L 33/60; H01L 27/15; H01L 33/20; H01L 33/38

(52) U.S. Cl. CPC H01L 33/60; H01L 27/156; H01L 33/20; H01L 33/382

(57) ABSTRACT

Reduction of the maximum luminance is suppressed. A semiconductor device according to an embodiment includes a light emitter (105) provided on an upper surface of a substrate, a metal microstructure (108) disposed on a side opposite to the substrate with the light emitter interposed therebetween and spaced apart from the light emitter by a predetermined distance, and a reflector (109) provided on the substrate so as to partition adjacent semiconductor devices.

### FIELD

The present disclosure relates to a semiconductor device and a display device.

### BACKGROUND

In recent years, a flat (flat panel) display device has been the mainstream. As one of flat display devices, there is a display device using, as a light emitter (light emitting element) of a pixel, a so-called current drive type electrooptical element in which light emission luminance changes according to a current value flowing through a device. Examples of the current drive type electrooptical element include a light emitting diode (LED) and an organic electroluminescence (EL) element.

### CITATION LIST

### Patent Literature

Patent Literature 1: JP 2007-19467 A

### SUMMARY

### Technical Problem

However, in a conventional electrooptical element, since light extraction efficiency is reduced such as due to total reflection on an emission surface, there is a problem that maximum luminance is reduced.

In addition, since the conventional electrooptical element has a wide emission angle and a large part of light is emitted in unintended directions, light utilization efficiency is reduced, also resulting in reduced maximum luminance.

Therefore, the present disclosure proposes a semiconductor device and a display device capable of suppressing reduction of the maximum luminance.

### Solution to Problem

To solve the problems described above, a semiconductor device according to an embodiment of the present disclosure includes: a light emitter provided on an upper surface of a substrate; a microstructure made of metal disposed on a side opposite to the substrate with the light emitter interposed between the microstructure and the substrate, the microstructure being spaced apart from the light emitter by a predetermined distance; and a reflector provided on the substrate, the reflector partitioning the semiconductor device and an adjacent semiconductor device.

### BRIEF DESCRIPTION OF DRAWINGS

FIG. 1 is a schematic cross-sectional view illustrating a partial cross-sectional structure of a general electrooptical element.

FIG. 2 is a diagram illustrating a fine uneven metal structure using surface plasmon resonance according to a first embodiment.

FIG. 3 is a schematic cross-sectional view illustrating a partial cross-sectional structure of an electrooptical element provided with the fine uneven metal structure using the surface plasmon resonance according to the first embodiment.

FIG. 4 is a diagram illustrating presence or absence of a metallic nanoantenna structure and photoluminescence intensity of re-emitted light from each structure.

FIG. 5 is a diagram illustrating a relationship of a distance between exciton and metallic nanoantenna structure and normalized PL enhancement.

FIG. 6 is a cross-sectional view illustrating a schematic structural example of a semiconductor light-emitting element according to the first embodiment.

FIG. 7 is a perspective view illustrating a configuration example of a metallic nanoantenna structure according to the first embodiment.

FIG. 8 is a top view illustrating a configuration example of a reflector according to a first example of the first embodiment.

FIG. 9 is a top view illustrating a structural example of a reflector according to a second example of the first embodiment.

FIG. 10 is a cross-sectional view illustrating a schematic configuration example of a semiconductor light-emitting element according to a first modified example of the first embodiment.

FIG. 11 is a cross-sectional view illustrating a schematic configuration example of a semiconductor light-emitting element according to a second modified example of the first embodiment.

FIG. 12 is a cross-sectional view illustrating a schematic configuration example of a semiconductor light-emitting element according to a third modified example of the first embodiment.

FIG. 13 is a cross-sectional view illustrating a schematic configuration example of a semiconductor light-emitting element according to a fourth modified example of the first embodiment.

FIG. 14 is a cross-sectional view illustrating a schematic configuration example of a semiconductor light-emitting element according to a fifth modified example of the first embodiment.

FIG. 15 is a cross-sectional view illustrating a schematic configuration example of a semiconductor light-emitting element according to a sixth modified example of the first embodiment.

FIG. 16 is a cross-sectional view illustrating a schematic configuration example of a semiconductor light-emitting element according to a seventh modified example of the first embodiment.

FIG. 17 is a cross-sectional view illustrating a schematic configuration example of a semiconductor light-emitting element according to an eighth modified example of the first embodiment.

FIG. 18 is a perspective view illustrating an arrangement structural example of a metallic nanoantenna structure according to a ninth modified example of the first embodiment.

FIG. 19 is a perspective view illustrating an arrangement structural example of a metallic nanoantenna structure according to a tenth modified example of the first embodiment.

FIG. 20 is a perspective view illustrating an arrangement structural example of a metallic nanoantenna structure according to an eleventh modified example of the first embodiment.

FIG. 21 is a perspective view illustrating an example of a columnar structure according to a twelfth modified example of the first embodiment.

FIG. 22 is a perspective view illustrating an example of a columnar structure according to a thirteenth modified example of the first embodiment.

FIG. 23 is a perspective view illustrating another example of the columnar structure according to the thirteenth modified example of the first embodiment.

FIG. 24 is a perspective view illustrating an example of a columnar structure according to a fourteenth modified example of the first embodiment.

FIG. 25 is a perspective view illustrating another example of the columnar structure according to the fourteenth modified example of the first embodiment.

FIG. 26 is a perspective view illustrating still another example of the columnar structure according to the fourteenth modified example of the first embodiment.

FIG. 27 is a schematic cross-sectional view illustrating a partial cross-sectional structure of an electrooptical element when the reflector according to the first embodiment or the modified examples thereof is not provided.

FIG. 28 is a cross-sectional view illustrating a schematic structural example of a microsemiconductor light-emitting element according to a second embodiment.

FIG. 29 is a cross-sectional view illustrating a schematic configuration example of a microsemiconductor light-emitting element according to a first modified example of the second embodiment.

FIG. 30 is a cross-sectional view illustrating a schematic configuration example of a microsemiconductor light-emitting element according to a second modified example of the second embodiment.

FIG. 31 is a cross-sectional view illustrating a schematic configuration example of a microsemiconductor light-emitting element according to a third modified example of the second embodiment.

FIG. 32 is a schematic diagram illustrating a configuration example of a display device according to a third embodiment.

FIG. 33 is a block diagram illustrating an overall configuration example of the display device according to the third embodiment.

FIG. 34 is a front view of a lens interchangeable mirrorless type digital still camera to which a display device according to a fourth embodiment is applied.

FIG. 35 is a rear view of the lens interchangeable mirrorless type digital still camera to which the display device according to the fourth embodiment is applied.

FIG. 36 is an external view of a head mounted display to which the display device according to the fourth embodiment is applied.

### DESCRIPTION OF EMBODIMENTS

Hereinafter, embodiments of the present disclosure will be described with reference to the drawings. In the following embodiments, same parts are given the same reference signs to omit redundant description.

The present disclosure will be described according to the following item order.
1. First Embodiment
   1.1 Structural example of semiconductor light-emitting element
   1.2 Action and effect
   1.3 Modified examples
      1.3.1 First modified example
      1.3.2 Second modified example
      1.3.3 Third modified example
      1.3.4 Fourth modified example
      1.3.5 Fifth modified example
      1.3.6 Sixth modified example
      1.3.7 Seventh modified example
      1.3.8 Eighth modified example
      1.3.9 Ninth modified example
      1.3.10 Tenth modified example
      1.3.11 Eleventh modified example
      1.3.12 Twelfth modified example
      1.3.13 Thirteenth modified example
      1.3.14 Fourteenth modified example
2. Second Embodiment
   2.1 Structural example of microsemiconductor light-emitting element
   2.2 Action and effect
   2.3 Modified examples
      2.3.1 First modified example
      2.3.2 Second modified example
      2.3.3 Third modified example
3. Third Embodiment
4. Fourth Embodiment

### 1. First Embodiment

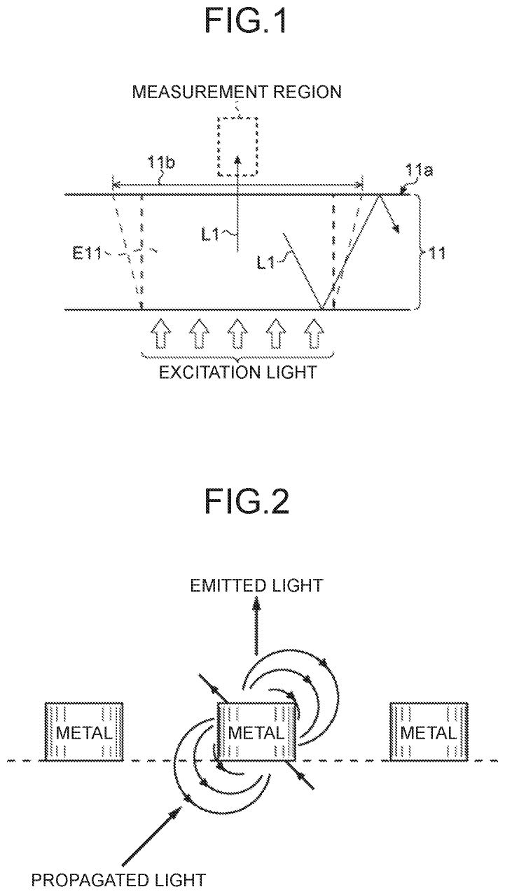

First, a general electrooptical element will be described before describing a semiconductor device and a display device according to a first embodiment of the present disclosure. FIG. 1 is a schematic cross-sectional view illustrating a partial cross-sectional structure of the general electrooptical element. The cross section in the following description may be a plane perpendicular to a main plane (e.g., element forming surface) of the substrate.

As illustrated in FIG. 1, in the general electrooptical element, excitation light is applied to a fluorescent layer 11 from a back surface side, and light L1 generated in the fluorescent layer 11 is emitted from an emission surface 11a of the fluorescent layer 11 to emit light.

However, in the structure of the general electrooptical element, due to a difference in refractive index between the fluorescent layer 11 and its upper layer, a part of the light L1 generated in the fluorescent layer 11 is reflected or totally reflected by the emission surface 11a. Then, extraction efficiency of the light L1 from an emission region 11b with respect to incident excitation light decreases. As a result, for example, the maximum luminance observed in a measurement region decreases.

In addition, in the general electrooptical element, since the light L1 generated in the fluorescent layer 11 is emitted at a wide angle, large part of light is emitted in unintended directions. Therefore, an amount of the light L1 emitted from the emission region 11b and propagated in a target direction decreases. This decreases utilization efficiency of the light L1, and as a result, for example, the maximum luminance observed in the measurement region decreases.

Therefore, the present embodiment enables to suppress a light amount of the light L1 reflected by the emission surface 11a and to control the direction of the light L1 emitted from the emission region 11b. As a result, it is possible to suppress a decrease in the extraction efficiency of the light L1 from the emission region 11b and a decrease in the utilization efficiency of the light L1 emitted from the emission region 11b, and thus, reduction of the maximum luminance can be suppressed. Furthermore, by suppressing a decrease in the extraction efficiency of the light L1 from the emission region 11b and a decrease in the utilization efficiency of the light L1 emitted from the emission region 11b, it is also possible to suppress an intensity of the excitation light incident on the fluorescent layer 11. Accordingly, it is also possible to achieve effects such as improvement in current efficiency and reduction of power consumption.

As a configuration for achieving improved light extraction efficiency and improved light utilization efficiency, for example, a fine uneven metal structure (hereinafter, also referred to as a metallic nanoantenna structure.) using surface plasmon resonance as illustrated in FIG. 2 can be used.

When photons enter the metallic nanoantenna structure illustrated in FIG. 2, the incident photons are coupled as localized surface plasmon polariton to vibrate electrons on a metal surface and form an oscillating electric field. Then, the oscillating electric field re-emits energy as new scattering light.

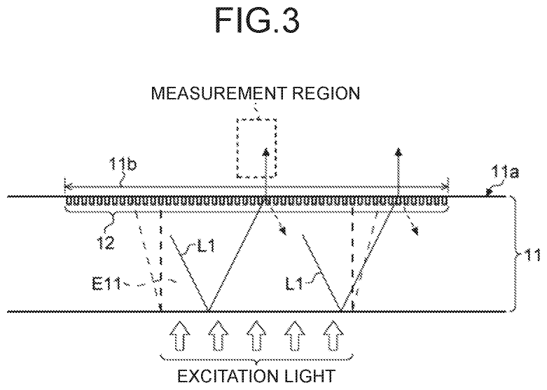

Therefore, as illustrated in FIG. 3, by providing a metallic nanoantenna structure 12 having characteristics as described above at least in the emission region 11b on the emission surface 11a, the light L1 generated in the fluorescent layer 11 and entering the metallic nanoantenna structure 12 can be efficiently emitted from the emission region 11b. Accordingly, the light extraction efficiency can be improved.

In addition, by giving periodicity to the metallic nanoantenna structure 12, directivity is given to the emitted light L1. Therefore, by controlling a period of the metallic nanoantenna structure 12, it is possible to control a light emission direction to emit the light in a target direction. Accordingly, the light utilization efficiency can be improved.

However, when an exciton such as an LED or an organic EL for exciting the fluorescent layer 11 and the metallic nanoantenna structure 12 are close to each other, the exciton and the metallic nanoantenna structure 12 may become coupled. For example, when an exciton originally having a high internal quantum efficiency (IQE) is used, such as an organic EL using phosphorescence, coupling of the exciton and the metallic nanoantenna structure 12 may decrease internal quantum efficiency. As a result, the current efficiency may be decreased or power consumption may be increased.

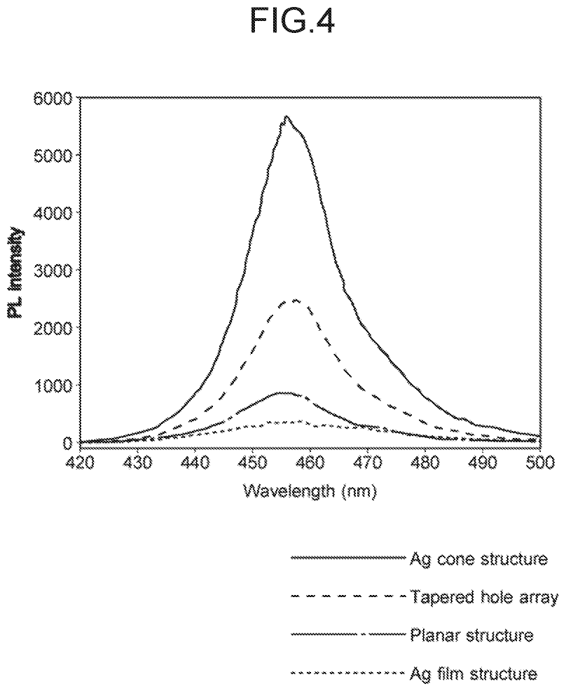

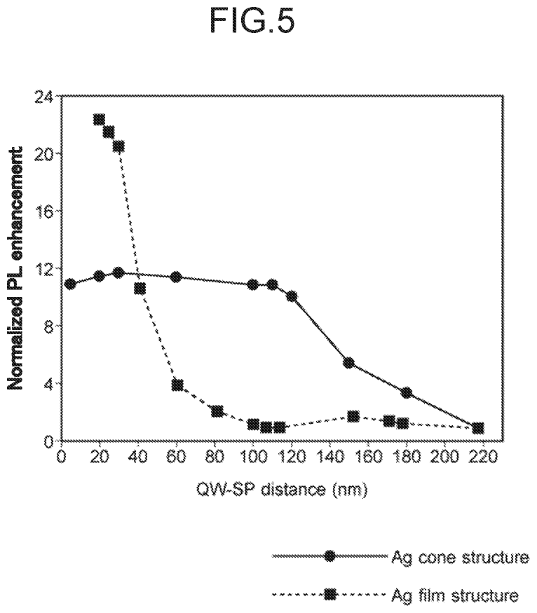

FIG. 4 illustrates presence or absence of the metallic nanoantenna structure and the photoluminescence (PL) intensity) of re-emitted light from each structure, and FIG. 5 illustrates a relationship of a distance between the exciton and the metallic nanoantenna structure (QW-SP distance) and normalized PL enhancement. Note that, in FIG. 4, as the metallic nanoantenna structure, an Ag cone structure and a tapered hole array are given as an example, and as the structure not having the metallic nanoantenna structure, a plannar structure and an Ag film structure are given as an example. In addition, in FIG. 5, the Ag cone structure and the Ag film structure are illustrated as an example.

As illustrated in FIG. 4, the PL intensity of the re-emitted light is stronger when the Ag cone structure or the Ag film structure is provided than when these are not provided (tapered hole array and planar structure), and a wavelength at peak intensity is about 455 nm. In addition, as illustrated in FIG. 5, when the Ag cone structure or the Ag film is provided, the normalized PL enhancement increases as a distance between the Ag structure and the exciton decreases. For example, when the Ag film is provided, the normalized PL enhancement between the Ag film and the exciton is enhanced in a case where the Ag film and the exciton are closer than about 150 nanometer (nm) (e.g., equivalent to about ⅓ of wavelength of re-emitted light). In addition, when the Ag cone structure is provided, coupling between the cone structure and the exciton is enhanced when the cone structure and the exciton are closer than about 110 nm (e.g., equivalent to about ¼ of wavelength of re-emitted light).

Therefore, in the present embodiment, in order to achieve improved light extraction efficiency and improved light utilization efficiency while maintaining high IQE of the exciton, the exciton and the metallic nanoantenna structure 12 are separated to some extent. For example, the distance between the exciton and the metallic nanoantenna structure 12 is set to ¼ or more, more preferably ⅓ or more, of the wavelength of a target emission light (re-emitted light). This makes it possible to suppress coupling between the exciton and the metallic nanoantenna structure 12 and to efficiently couple the photon and the metallic nanoantenna structure 12, so that it is possible to suppress a decrease in the current efficiency and an increase in the power consumption due to a decrease in the internal quantum efficiency.

### 1.1 Structural Example of Semiconductor Light-Emitting Element

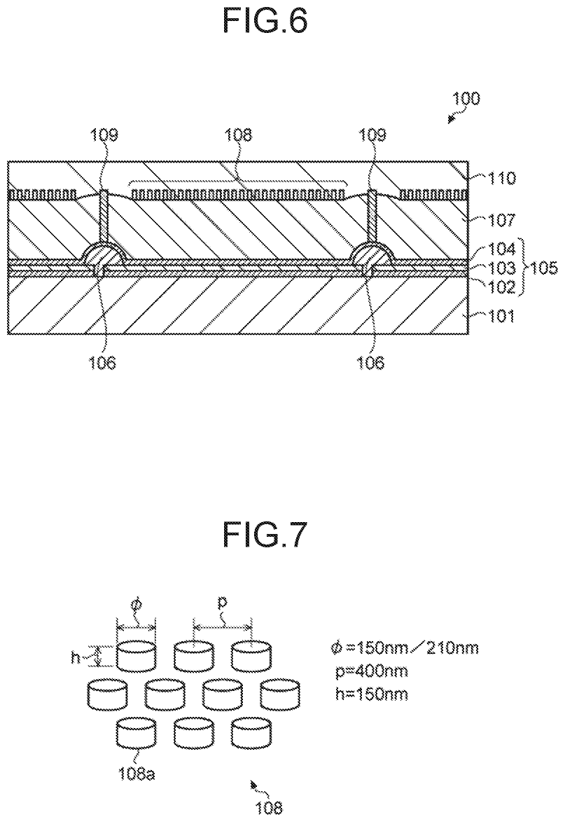

Next, a structural example of a semiconductor light-emitting element (hereinafter also simply referred to as a pixel) as the semiconductor device according to the present embodiment will be described in detail with reference to the drawings. FIG. 6 is a cross-sectional view illustrating a schematic structural example of the semiconductor light-emitting element according to the present embodiment.

As illustrated in FIG. 6, a semiconductor light-emitting element 100 according to the present embodiment includes a substrate 101, a light emitter 105 as the exciton provided on an element forming surface (also referred to as an upper surface) of the substrate 101, a passivation layer 107 provided on the light emitter 105, a metallic nanoantenna structure 108 provided on an upper surface of the passivation layer 107, a planarization film 110 covering the upper surface of the passivation layer 107 provided with the metallic nanoantenna structure 108, a reflector 109 as an element isolation part that partitions each semiconductor light-emitting element 100, and an insulator 106 located on at least partially between elements partitioned by the reflector 109 on the element forming surface of the substrate 101.

In addition to a semiconductor substrate such as a silicon substrate, the substrate 101 may be, for example, a gallium nitride (GaN) substrate, a gallium arsenide (GaAs) substrate, a sapphire substrate, a silicon carbide (Sic) substrate, a high strain point glass substrate, a soda glass (Na₂O·CaO·SiO₂) substrate, a borosilicate glass (Na₂O·B₂O₃·SiO₂) substrate, a forsterite (2MgO·SiO₂) substrate, a lead glass (Na₂O·PbO·SiO₂) substrate, various glass substrates having an insulating material layer formed on a surface thereof, a quartz substrate, a quartz substrate having an insulating material layer formed on a surface thereof, a substrate formed of an organic polymer (having a form of a polymer material such as a flexible plastic film, plastic sheet, or plastic substrate made of a polymer material) exemplified by polymethyl methacrylate (PMMA), polyvinyl alcohol (PVA), polyvinyl phenol (PVP), polyethersulfone (PES), polyimide, polycarbonate, polyethylene terephthalate (PET), and polyethylene naphthalate (PEN).

In the present embodiment, for example, an organic EL element is used for the light emitter 105. In this case, the light emitter 105 includes a lower electrode (anode) 102 on a side of the substrate 101, an upper electrode (cathode) 104 on a side of the passivation layer 107, and an organic layer 103 that is a photoelectric converter provided between the lower electrode 102 and the upper electrode 104. However, the light emitter 105 is not limited to the organic EL element, and various light emitting elements such as an LED, a quantum dot LED, and a perovskite LED may be used.

The insulator 106 is made of, for example, a silicon nitride film (SiN), a silicon oxide film (SiO₂), a silicon oxynitride film (SiON), or an alumina film (Al₂O₃).

The passivation layer 107 is a transparent insulating layer with respect to light emitted from the light emitter 105, such as a silicon nitride film (SiN), a silicon oxide film (SiO₂), a silicon oxynitride film (SiON), and an alumina film (Al₂O₃), and is provided mainly for the purpose of blocking entry of water or oxygen during standby.

Furthermore, in the present embodiment, the passivation layer 107 also functions as a spacer layer for securing a distance between the light emitter 105, which is the exciton, and the metallic nanoantenna structure 12. Therefore, a layer thickness of the passivation layer 107 may be, for example, ¼ or more, more preferably ⅓ or more, of the target wavelength.

The planarization film 110 is a transparent insulating layer with respect to light emitted from the light emitter 105, such as a silicon nitride film (SiN), a silicon oxide film (SiO₂) and a resin layer whose surface is planarized, and the surface is planarized by chemical mechanical polishing (CMP) or the like.

The metallic nanoantenna structure 108 may be a structure made of various metals or alloys capable of generating surface plasmon, such as aluminum (Al), an aluminum alloy, gold (Au), and silver (Ag).

Here, FIG. 7 illustrates an example of the metallic nanoantenna structure 108 according to the present embodiment. FIG. 7 is a perspective view illustrating a configuration example of an excerpt of the metallic nanoantenna structure according to the present embodiment. As illustrated in FIG. 7, the metallic nanoantenna structure 108 includes, for example, a structure in which columnar structures 108a having a columnar shape are arranged at equal intervals in a hexagonal close-packed structure (hereinafter also referred to as delta arrangement). A diameter ¢ of the columnar structure 108a may be, for example, 150 nm or 210 nm, a height h may be, for example, 150 nm, and a pitch p may be, for example, 400 nm. However, the present embodiment is not limited to these numerical values, and various modifications may be made according to a target wavelength and an emission direction. For example, when the display device including the semiconductor light-emitting element 100 expresses a color space with three primary colors of RGB, the diameter ϕ, the height h, and the pitch p of the metallic nanoantenna structure 108 of each semiconductor light-emitting element 100 may be designed to have different values in an R pixel, a G pixel, and a B pixel.

The reflector 109 is made of a material that reflects light having the target wavelength, such as a metal or alloy of tungsten (W), aluminum (Al), and copper (Cu), or a dielectric multilayer film, thereby physically and optically separating adjacent semiconductor light-emitting elements 100. Note that the reflector 109 may have a hollow structure that reflects light by an air gap. In the present embodiment, the reflector 109 penetrates the passivation layer 107 and reaches the insulator 106 and the upper electrode 104 of the light emitter 105.

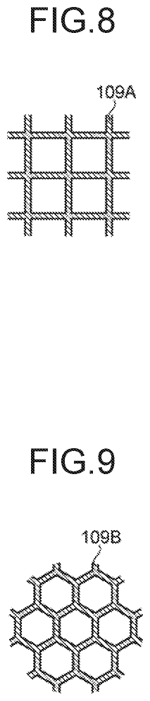

Here, FIGS. 8 and 9 illustrate examples of an excerpt of the reflector 109 according to the present embodiment. FIG. 8 is a top view illustrating a configuration example of the reflector according to a first example, and FIG. 9 is a top view illustrating a structural example of a reflector according to a second example.

As illustrated in FIG. 8, a reflector 109A according to the first example has a lattice-like structure (hereinafter also referred to as a square arrangement) including a reflective film extending in a row direction and a reflective film extending in a column direction. The lattice structure partitions the element forming surface of the substrate 101 into a two-dimensional lattice shape. Each semiconductor light-emitting element 100 is provided in each region partitioned by the reflector 109A.

In addition, as illustrated in FIG. 9, a reflector 109B according to the second example has a honeycomb structure and partitions the element forming surface of the substrate 101 into a hexagonal close-packed structure. Each semiconductor light-emitting element 100 is provided in each region partitioned by the reflector 109B.

Note that, when the reflector 109 is made of a conductor such as a metal or an alloy, the reflector 109 can have a function as an auxiliary electrode by bringing the reflector 109 into contact with the upper electrode 104 of the light emitter 105, so that shading due to potential drop can be suppressed.

### 1.2 Action and Effect

As described above, according to the present embodiment, by providing the fine uneven metal structure (metallic nanoantenna structure 108) coupled to the photon by localized surface plasmon resonance on the upper surface of the passivation layer 107, which is the light emission surface, reflection on the emission surface is suppressed. Therefore, it is possible to improve the light extraction efficiency and suppress reduction of the maximum luminance.

In addition, by providing the passivation layer 107 between the light emitter 105, which is the exciton, and the metallic nanoantenna structure 108, coupling of the light emitter 105 and the metallic nanoantenna structure 108 is suppressed. Therefore, it is possible to suppress reduction of the maximum luminance by suppressing a decrease in the current efficiency and an increase in power consumption due to a decrease in internal quantum efficiency of the excitons.

Furthermore, by adjusting the diameter ϕ, the height h, and the pitch p of the metallic nanoantenna structure 108, it is possible to control the emission direction of the re-emitted light. Therefore, it is possible to suppress reduction of the maximum luminance by reducing the light emitted in an unintended direction to improve the light utilization efficiency.

Furthermore, since individual semiconductor light-emitting elements 100 are optically separated by the reflector 109 that reflects light, leakage of light to adjacent pixels is reduced by a light leakage prevention effect of the reflector 109. Therefore, it is possible to suppress reduction of the maximum luminance by improving the light utilization efficiency.

### 1.3 Modified Examples

Next, modifications of the present embodiment will be described with some examples.

### 1.3.1 First Modified Example

FIG. 10 is a cross-sectional view illustrating a schematic configuration example of a semiconductor light-emitting element according to a first modified example. As illustrated in FIG. 10, a semiconductor light-emitting element 100A according to the first modified example further includes a color filter 111 provided on the planarization film 110 and an on-chip lens 112 provided on the color filter 111 in the same configuration as the semiconductor light-emitting element 100 described above with reference to FIG. 6.

In the semiconductor light-emitting element 100A of the R pixel, for example, the color filter 111 selectively transmits a red wavelength component. In the semiconductor light-emitting element 100A of the G pixel, for example, the color filter 111 selectively transmits a green wavelength component. In the semiconductor light-emitting element 100A of the B pixel, for example, the color filter 111 selectively transmits a blue wavelength component.

Note that the metallic nanoantenna structure 108 itself can also function as a surface plasmon resonance filter having wavelength selectivity. However, a combination of the metallic nanoantenna structure 108 and the color filter 111 can correct a wavelength spectrum of light emitted from the semiconductor light-emitting element 100A to a more ideal wavelength spectrum. Furthermore, for example, even when the light output from the light emitter 105 of each of the semiconductor light-emitting elements 100A is light in a visible light region having a broad wavelength spectrum, the combination of the surface plasmon resonance filter having the metallic nanoantenna structure 108 and the color filter 111 can correct the wavelength spectrum of the light emitted from the semiconductor light-emitting elements 100A to be closer to a target wavelength spectrum.

The on-chip lens 112 controls a propagation direction and a divergence angle of light emitted from the semiconductor light-emitting element 100A. By providing this on-chip lens 112, light emitted in an unintended direction is further reduced to improve the light utilization efficiency. Therefore, it is possible to suppress reduction of the maximum luminance.

Note that the on-chip lens 112 may be provided on the semiconductor light-emitting element 100A on a one-to-one basis, or may be provided at a ratio of one for a plurality of semiconductor light-emitting elements 100A.

### 1.3.2 Second Modified Example

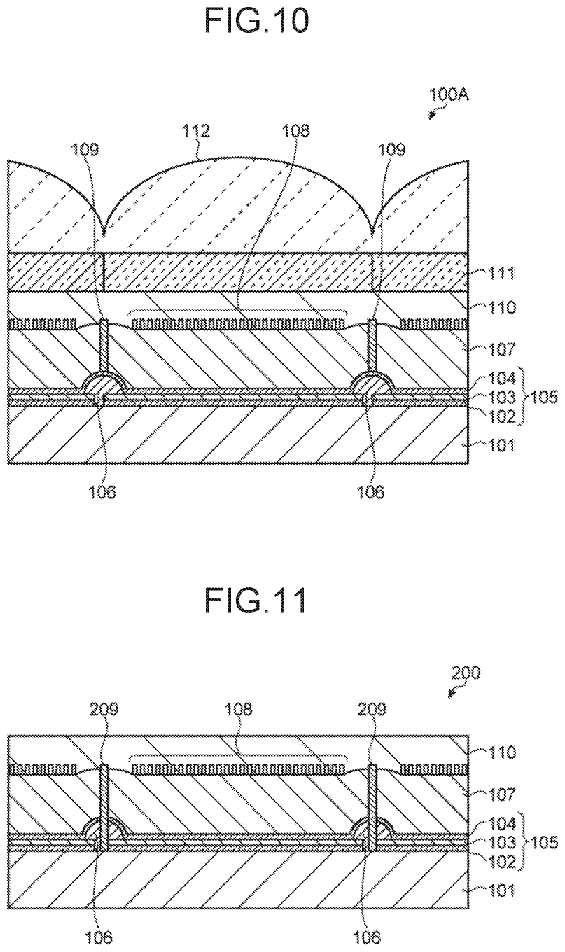

FIG. 11 is a cross-sectional view illustrating a schematic configuration example of a semiconductor light-emitting element according to a second modified example. As illustrated in FIG. 11, a semiconductor light-emitting element 200 according to the second modified example has a configuration in which the reflector 109 is replaced with a reflector 209 in the same configuration as the semiconductor light-emitting element 100 described above with reference to FIG. 6.

The reflector 209 penetrates the passivation layer 107 and reaches the element forming surface of the substrate 101. In the present modified example, the reflector 209 is not electrically connected to the lower electrode 102 of the light emitter 105. The reflector 209 may or may not be electrically connected to the upper electrode 104 of the light emitter 105.

In this manner, by providing the reflector 209 that reaches the element forming surface of the substrate 101, it is possible to further suppress leakage of light between adjacent pixels. Therefore, the light utilization efficiency can be further improved to suppress reduction of the maximum luminance.

### 1.3.3 Third Modified Example

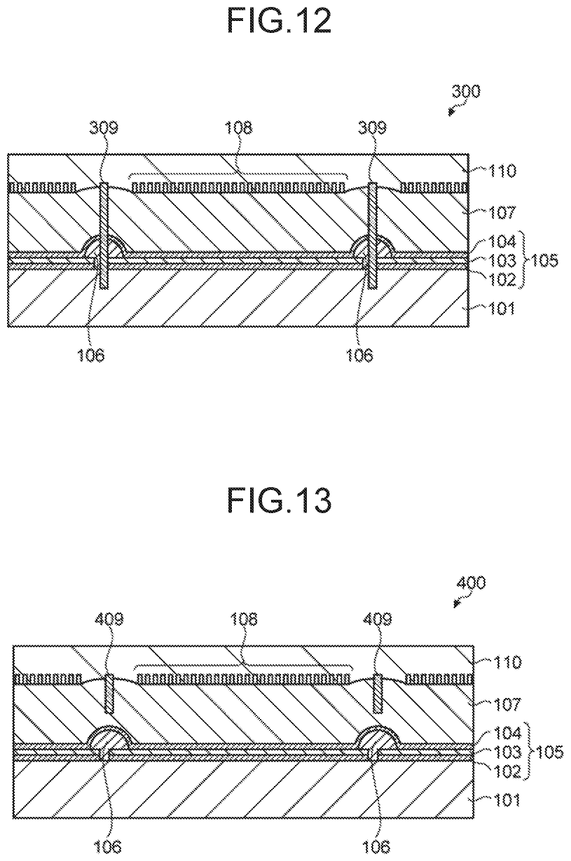

FIG. 12 is a cross-sectional view illustrating a schematic configuration example of a semiconductor light-emitting element according to a third modified example. As illustrated in FIG. 12, a semiconductor light-emitting element 300 according to the third modified example has a configuration in which the reflector 109 is replaced with a reflector 309 in the same configuration as the semiconductor light-emitting element 100 described above with reference to FIG. 6.

The reflector 309 penetrates through the passivation layer 107 and reaches an upper layer of the substrate 101. In the present modified example, the reflector 309 is not electrically connected to the lower electrode 102 of the light emitter 105. The reflector 309 may or may not be electrically connected to the upper electrode 104 of the light emitter 105.

In this manner, by providing the reflector 309 that reaches the upper layer of the substrate 101, it is possible to further suppress leakage of light between adjacent pixels. Therefore, the light utilization efficiency can be further improved to suppress reduction of the maximum luminance.

### 1.3.4 Fourth Modified Example

FIG. 13 is a cross-sectional view illustrating a schematic configuration example of a semiconductor light-emitting element according to a fourth modified example. As illustrated in FIG. 13, a semiconductor light-emitting element 400 according to the fourth modified example has a configuration in which the reflector 109 is replaced with a reflector 409 in the same configuration as the semiconductor light-emitting element 100 described above with reference to FIG. 6.

The reflector 409 is provided so as not to reach the upper electrode 104 or the insulator 106 from the upper surface of the passivation layer 107. Therefore, in the present modified example, the reflector 409 is not connected to the upper electrode 104 and the lower electrode 102.

As described above, even in a structure in which the reflector 409 is not connected to the upper electrode 104, it is possible to suppress leakage of light between adjacent pixels. Therefore, the light utilization efficiency can be further improved to suppress reduction of the maximum luminance.

A distance from a lower end of the reflector 409 to an upper end of the upper electrode 104 or the insulator 106, i.e., a gap between the reflector 409 and the upper electrode 104 or the insulator 106, may be equal to or less than the target wavelength. However, it is more desirable that the reflector 409 is in proximity with the upper electrode 104 or the insulator 106 to an extent of no gap or only an ignorable gap therebetween.

### 1.3.5 Fifth Modified Example

FIG. 14 is a cross-sectional view illustrating a schematic configuration example of a semiconductor light-emitting element according to a fifth modified example. As illustrated in FIG. 14, in a semiconductor light-emitting element 500 according to the fifth modified example, the reflector 209 is replaced with a reflector 509 and the insulator 106 is omitted in the same configuration as the semiconductor light-emitting element 200 described above with reference to FIG. 11.

The reflector 509 penetrates the passivation layer 107 and reaches the element forming surface of the substrate 101. The reflector 509 has a tapered shape whose cross-sectional area decreases from a bottom surface to a top surface. In the present modified example, the reflector 509 is not electrically connected to the lower electrode 102 of the light emitter 105. The reflector 509 may or may not be electrically connected to the upper electrode 104 of the light emitter 105.

As described above, by forming the reflector 509 in the tapered shape, a traveling direction of the light reflected by the reflector 509 can be brought close to a direction toward the metallic nanoantenna structure 108. This makes it possible to reduce the number of times of reflection on the reflector 509. Therefore, it is possible to reduce losses due to reflection to suppress reduction of the maximum luminance.

In the present modified example, the reflector 509 has the tapered shape whose cross-sectional area decreases from the bottom surface to the top surface. However, the shape is not limited thereto, and may be a reverse tapered shape whose cross-sectional area decreases from the top surface to the bottom surface. Furthermore, in the present modified example, the above-described second modified example is used as a base configuration. However, the present modified example is not limited thereto, and the first embodiment or other modified examples may be used as the base configuration.

### 1.3.6 Sixth Modified Example

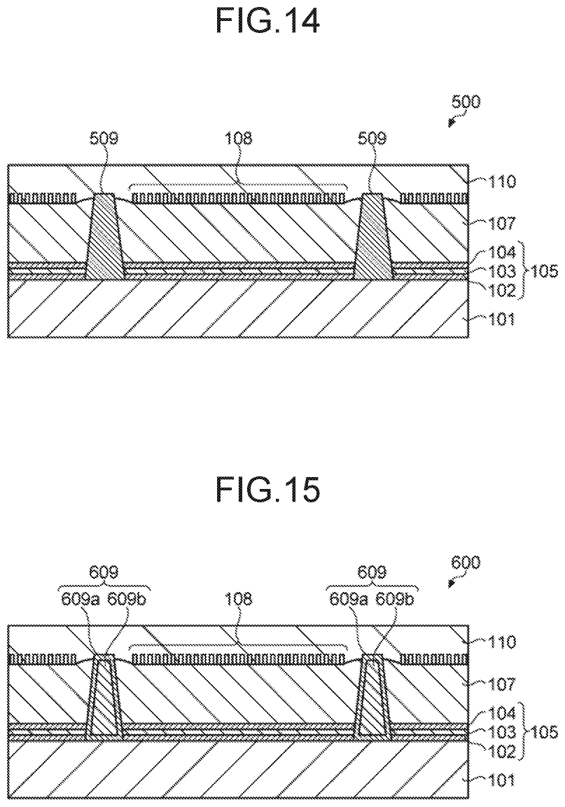

FIG. 15 is a cross-sectional view illustrating a schematic configuration example of a semiconductor light-emitting element according to a sixth modified example. As illustrated in FIG. 15, in a semiconductor light-emitting element 600 according to the sixth modified example, the reflector 509 is replaced with a reflector 609 in the same configuration as the semiconductor light-emitting element 500 described above with reference to FIG. 14.

The reflector 609 penetrates the passivation layer 107 and reaches the element forming surface of the substrate 101. The reflector 609 has a tapered shape in which a cross-sectional area decreases from a bottom surface to a top surface. Furthermore, the reflector 609 has a multilayer structure in which a surface is formed of a reflective film 609a such as metal, alloy, or a dielectric multilayer film, and an inside is formed of an insulating layer 609b such as silicon oxide or silicon nitride. In the present modified example, the reflector 609 is not electrically connected to the lower electrode 102 of the light emitter 105. The reflector 609 may or may not be electrically connected to the upper electrode 104 of the light emitter 105.

As described above, even when the reflector 609 has the tapered shape having the multilayer structure, the number of reflections on the reflector 609 can be reduced. Therefore, losses due to reflection can be reduced to suppress reduction of the maximum luminance.

Furthermore, in the present modified example, the above-described fifth modified example is used as a base configuration. However, the present modified example is not limited thereto, and the first embodiment or other modified examples may be used as the base configuration.

### 1.3.7 Seventh Modified Example

FIG. 16 is a cross-sectional view illustrating a schematic configuration example of a semiconductor light-emitting element according to a seventh modified example. As illustrated in FIG. 16, a semiconductor light-emitting element 700 according to the seventh modified example has a configuration in which the reflector 109 is replaced with a reflector 709 in the same configuration as the semiconductor light-emitting element 100 described above with reference to FIG. 6.

The reflector 709 reaches the element forming surface of the substrate 101 from the middle of the passivation layer 107. In the present modified example, the reflector 709 is not electrically connected to the lower electrode 102 of the light emitter 105. The reflector 709 may or may not be electrically connected to the upper electrode 104 of the light emitter 105.

As described above, even when the reflector 709 does not reach the upper surface of the passivation layer 107, leakage of light between adjacent pixels can be suppressed. Therefore, the light utilization efficiency can be further improved to suppress reduction of the maximum luminance.

In a direction perpendicular to the element forming surface of the substrate 101, a distance from an upper end of the reflector 709 to a lower end of the metallic nanoantenna structure 108, i.e., a gap formed by the reflector 409, may be equal to or less than a target wavelength A. In addition, in a direction parallel to the element forming surface of the substrate 101, a distance from a side end of the reflector 709 to a side end of the metallic nanoantenna structure 108, i.e., a gap between the reflector 409 and the metallic nanoantenna structure 108, may be equal to or less than the target wavelength. Furthermore, in the present modified example, the above-described first modified example is used as a base configuration. However, the present modified example is not limited thereto, and other modified examples of the first embodiment may be used as the base configuration.

### 1.3.8 Eighth Modified Example

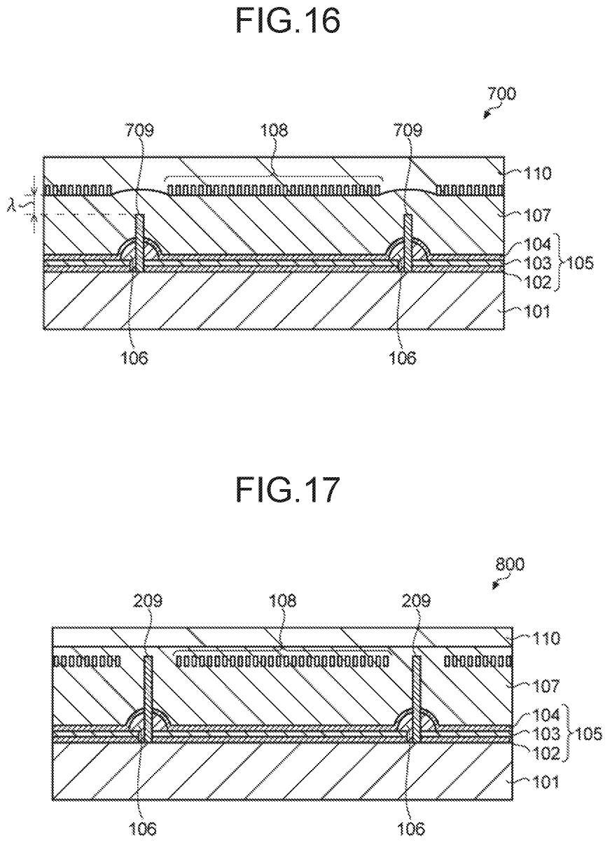

FIG. 17 is a cross-sectional view illustrating a schematic configuration example of a semiconductor light-emitting element according to an eighth modified example. As illustrated in FIG. 17, a semiconductor light-emitting element 800 according to the eighth modified example has a configuration in which the metallic nanoantenna structure 108 is embedded in an upper layer of the passivation layer 107 in the same configuration as the semiconductor light-emitting element 200 described above with reference to FIG. 11. In the present modified example, the upper end of the reflector 209 may or may not reach the upper surface of the passivation layer 107.

As described above, even when the metallic nanoantenna structure 108 is embedded in the passivation layer 107, it is possible to suppress coupling between the light emitter 105 and the metallic nanoantenna structure 108 by maintaining a distance from the light emitter 105 to the metallic nanoantenna structure 108. Therefore, reduction of the maximum luminance can be suppressed by suppressing a decrease in the current efficiency and an increase in the power consumption due to a decrease in the internal quantum efficiency of the exciton.

In the present modified example, the above-described second modified example is used as a base configuration. However, the present modified example is not limited thereto, and the first embodiment or other modified examples may be used as the base configuration.

### 1.3.9 Ninth Modified Example

In a ninth modified example, a modification of the arrangement structure of the metallic nanoantenna structure 108 will be described. FIG. 18 is a perspective view illustrating an arrangement structure example of the metallic nanoantenna structure according to the ninth modified example. As illustrated in FIG. 18, a metallic nanoantenna structure 908 according to the ninth modified example has a structure in which columnar structures 108a to 108c having different diameters ¢ and/or heights h are arranged in a predetermined periodic array in an X direction and a Y direction.

As described above, by mixing the columnar structures 108a to 108c having different sizes and arranging them in the predetermined periodic array, light re-emitted from the metallic nanoantenna structure 908 can have a broad wavelength spectrum. This means that the wavelength spectrum of the light re-emitted from the metallic nanoantenna structure 908 can be more freely adjusted by mixing the columnar structures 108a to 108c having different sizes and adjusting their periods.

Note that, in the present modified example, a pitch p of each of the columnar structures 108a to 108c is fixed. However, the present modified example is not limited thereto, and various modifications may be made such as giving fluctuation to the pitch p of each of the columnar structures 108a to 108c.

### 1.3.10 Tenth Modified Example

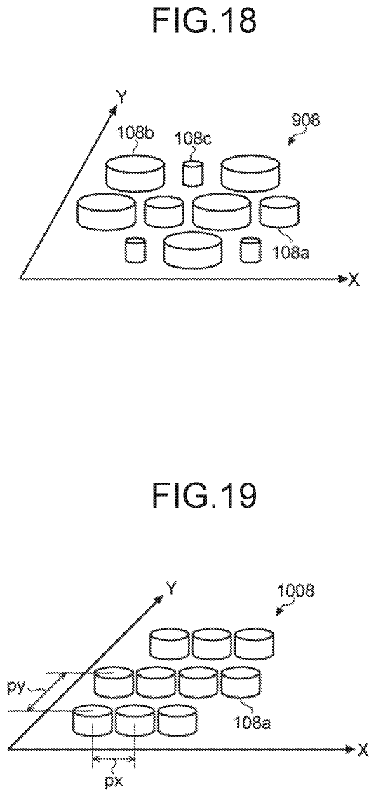

In a tenth modified example, another modification of the arrangement structure of the metallic nanoantenna structure 108 will be described. FIG. 19 is a perspective view illustrating an arrangement structure example of the metallic nanoantenna structure according to the tenth modified example. As illustrated in FIG. 19, in a metallic nanoantenna structure 1008 according to the tenth modified example, the plurality of columnar structures 108a is arranged such that a pitch px in the X direction is different from a pitch py in the Y direction.

As described above, by independently adjusting the pitch px in the X direction and the pitch py in the Y direction, it is possible to control the emission direction of light re-emitted from the metallic nanoantenna structure 1008. For example, it is also possible to adjust the pitch of the metallic nanoantenna structure 1008 so as to emit light in a direction perpendicular to the emission surface from the semiconductor light-emitting element 100 located near a center of the display device, and to adjust the pitch of the metallic nanoantenna structure 1008 so as to emit light in a direction inclined toward the center from the semiconductor light-emitting element 100 located near a peripheral edge.

### 1.3.11 Eleventh Modified Example

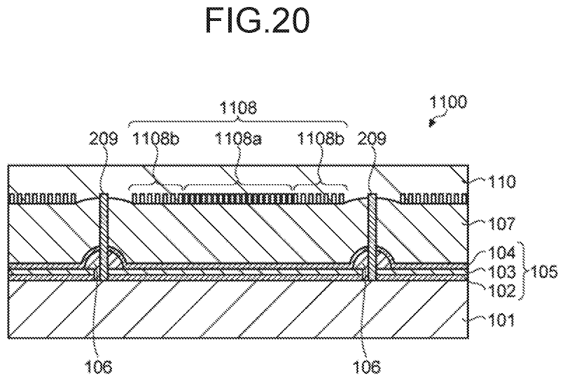

In an eleventh modified example, still another modification of the arrangement structure of the metallic nanoantenna structure 108 will be described. FIG. 20 is a perspective view illustrating an arrangement structure example of the metallic nanoantenna structure according to the eleventh modified example. As illustrated in FIG. 20, in a metallic nanoantenna structure 1108 according to the eleventh modified example, the pitch p is different between the columnar structure 108a located in a central portion 1108a of the pixel and the columnar structure 108a located in a peripheral portion 1108b of the pixel.

As described above, by changing the pitch p of the columnar structures 108a between the central portion 1108a and the peripheral portion 1108b of a pixel area in which each semiconductor light-emitting element 1100 is provided, it is possible to optimize the emission direction of light re-emitted from each portion even when, for example, an incident angle of light changes between the central portion 1108a and the peripheral portion 1108b.

Note that, in the present modified example, the pitch p of the columnar structure 108a is changed between the central portion 1108a and the peripheral portion 1108b of the pixel area. However, the present modified example is not limited thereto. For example, the diameter φ and/or the height h of the columnar structure 108a may be changed between the central portion 1108a and the peripheral portion 1108b of the pixel area. Furthermore, in the present modified example, the pixel area is divided into the central portion 1108a and the peripheral portion 1108b. However, the present modified example is not limited thereto. For example, various modifications may be made such that the pixel area is divided into left and right and/or top and bottom portions.

### 1.3.12 Twelfth Modified Example

In a twelfth modified example, modification of individual columnar structures 108a to 108c configuring the metallic nanoantenna structure 108 or 908 will be described.

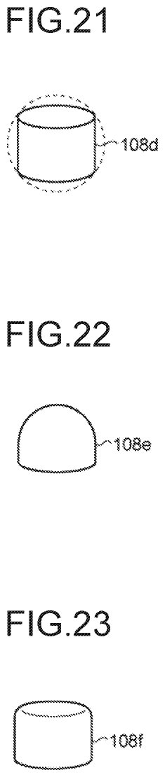

FIG. 21 is a perspective view illustrating an example of a columnar structure according to the twelfth modified example. As illustrated in FIG. 21, a columnar structure 108d according to the twelfth modified example is designed such that a ratio of the diameter φ to the height h is close to a sphere.

By bringing the ratio of the diameter φ to the height h close to the sphere, it is possible to reduce dependency of each columnar structure 108d on the incident angle. Therefore, incident light can be more efficiently taken in to re-emit.

### 1.3.13 Thirteenth Modified Example

In a thirteenth modified example, another modification of the individual columnar structures 108a to 108c configuring the metallic nanoantenna structure 108 or 908 will be described.

FIGS. 22 and 23 are perspective views illustrating examples of a columnar structure according to the thirteenth modified example. A columnar structure 108e illustrated in FIG. 22 has a dome shape on an upper side. A columnar structure 108f illustrated in FIG. 23 has a shape in which an edge on an upper surface side is rounded.

As described above, by adopting a configuration in which the edge close to a right angle is not provided on the upper surface side, it is possible to suppress specific localization of resonating electrons. Accordingly, specific variations of the individual columnar structures 108e or 108f can be suppressed. This makes it possible to suppress characteristic variations of the metallic nanoantenna structure 108 or 908.

### 1.3.14 Fourteenth Modified Example

In a fourteenth modified example, still another modification of the individual columnar structures 108a to 108c configuring the metallic nanoantenna structure 108 or 908 will be described.

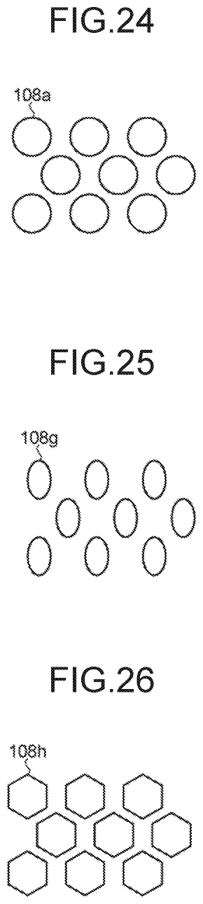

FIGS. 24 to 26 are perspective views illustrating examples of a columnar structure according to the fourteenth modified example. The columnar structure 108a illustrated in FIG. 24 has a circular columnar shape in which a shape as viewed from the top is circular. A columnar structure 108g illustrated in FIG. 25 has an elliptical columnar shape in which a shape as viewed from the top is elliptical. A columnar structure 108h illustrated in FIG. 26 has a polygonal columnar shape in which a shape viewed from the top is polygon such as hexagon.

As described above, the shape of each columnar structure viewed from the top (i.e., cross-sectional shape) is not limited to a circular shape, and may be variously modified including the elliptical shape and the polygonal shape. Furthermore, in the above description, the columnar structures 108a, 108g, and 108h are columnar. However, the present modified example is not limited thereto, and the columnar structures may have a tapered shape or a reverse tapered shape (i.e., frustum shape or inverted frustum shape), or may have a shape in which the edge on the upper surface side is rounded or a shape on the upper side is domed.

### 2. Second Embodiment

Next, a semiconductor device and a display device according to a second embodiment of the present disclosure will be described. In the present embodiment, for example, a case where the semiconductor light-emitting element according to the above-described embodiment or the modified examples thereof is applied to a micropixel having a minute size will be described.

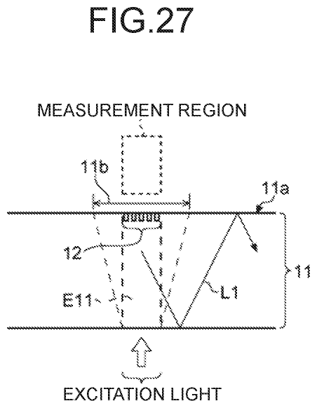

FIG. 27 is a schematic cross-sectional view illustrating a partial cross-sectional structure of the electrooptical element when the reflector according to the above-described embodiment or the modified examples thereof is not provided. As described in the first embodiment or the modified examples thereof, in a case where the reflector 109 or the like is not provided between adjacent pixels, the light emitted from the light emitter 105 is reflected by the upper surface of the passivation layer 107 and leaks to the adjacent pixels. Then, as illustrated in FIG. 27, an amount of light 11 leaking into the adjacent pixel increases as a pixel area is reduced.

Therefore, in the present embodiment, in the micropixel having a reduced pixel area, the reflector 109 is arranged between the adjacent pixels, thereby reducing leakage of light between the adjacent pixels. Note that the reflector provided between the adjacent pixels is not limited to the reflector 109, and may be any of the reflectors 109, 209, 309, 409, 509, 609, and 709 exemplified in the above-described embodiment or the modified examples thereof.

### 2.1 Structural Example of Microsemiconductor Light-Emitting Element

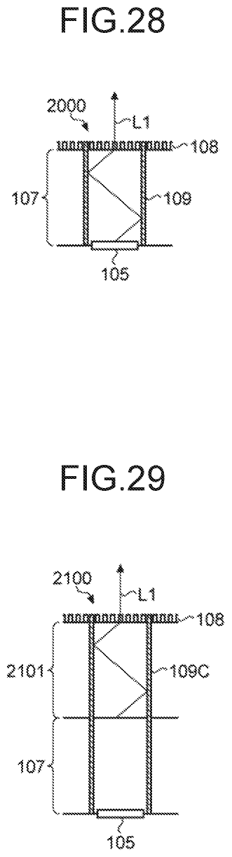

FIG. 28 is a cross-sectional view illustrating a schematic structural example of a microsemiconductor light-emitting element according to the present embodiment. However, in FIG. 28 and the following drawings, for simplification of description, illustration of the light emitter 105 is simplified, and the substrate 101, the planarization film 110, and the insulator 106 are omitted.

As illustrated in FIG. 28, a microsemiconductor light-emitting element 2000 according to the present embodiment has a configuration in which a pixel area (also referred to as an element area) is reduced in the same configuration as the semiconductor light-emitting element 100 described with reference to FIG. 6 in the first embodiment.

Note that the microsemiconductor light-emitting element 2000 may be, for example, a semiconductor light-emitting element in which lengths in the X direction and the Y direction (hereinafter simply referred to as a size) of the pixel area in a direction parallel to the element forming surface of the substrate 101 are about 20 μm or less. When this is applied to, for example, RGB pixels, the size of each pixel may be, for example, 8.1 μm, 7.8 μm, 6.3 μm, 5.1 μm, or the like. In this case, for example, in a case where the pixel array is in the delta arrangement, the size of the subpixel is about ⅓, and for example, in a case where the pixel array is in a square arrangement, the size of the subpixel is about ¼.

### 2.2 Action and Effect

As described above, by providing the reflector 109 that optically separates adjacent pixels from each other in the microsemiconductor light-emitting element 2000 having a reduced pixel area, leakage of light to the adjacent pixels is reduced by the light leakage prevention effect. Therefore, the light utilization efficiency can be further improved to suppress reduction of the maximum luminance.

Note that other configurations, effects, and modifications may be similar to those of the above-described embodiment or the modified examples thereof, and thus detailed description thereof is omitted here.

### 2.3 Modified Examples

Next, modifications of the present embodiment will be described with some examples.

### 2.3.1 First Modified Example

FIG. 29 is a cross-sectional view illustrating a schematic configuration example of a microsemiconductor light-emitting element according to a first modified example. As illustrated in FIG. 29, a microsemiconductor light-emitting element 2100 according to the first modified example has a configuration in which a quantum dot layer 2101 is disposed between the passivation layer 107 and the metallic nanoantenna structure 108, and the reflector 109 is replaced with a reflector 109C that penetrates the quantum dot layer 2101 and the passivation layer 107 and reaches the element forming surface of the substrate 101 in the same configuration as the microsemiconductor light-emitting element 2000 described above with reference to FIG. 28.

As described above, in the configuration in which the quantum dot layer 2101 is provided between the passivation layer 107 and the metallic nanoantenna structure 108, the reflector 109C is also provided on a side surface of the quantum dot layer 2101. As a result, leakage light to the adjacent pixels is reduced by the light leakage prevention effect. Therefore, the light utilization efficiency can be further improved to suppress reduction of the maximum luminance.

Note that, in FIG. 29, the semiconductor light-emitting element 200 according to the second modified example of the first embodiment is applied to the microsemiconductor light-emitting element 2000 illustrated in FIG. 28, but the present modified example is not limited thereto, and either the first embodiment or the modified examples thereof may be applied.

### 2.3.2 Second Modified Example

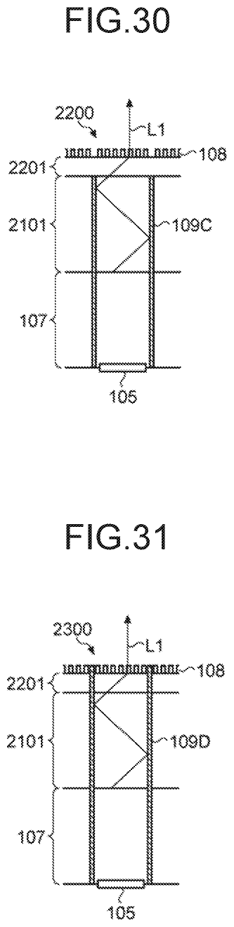

FIG. 30 is a cross-sectional view illustrating a schematic configuration example of a microsemiconductor light-emitting element according to a second modified example. As illustrated in FIG. 30, a microsemiconductor light-emitting element 2200 according to the second modified example has a configuration in which a planarization film 2201 is arranged on the quantum dot layer 2101 and the metallic nanoantenna structure 108 is arranged on the planarization film 2201 in the same configuration as the microsemiconductor light-emitting element 2100 described above with reference to FIG. 29.

As described above, by providing the planarization film 2201 on the quantum dot layer 2101 and providing the metallic nanoantenna structure 108 on a surface of the planarization film 2201, a process accuracy of the metallic nanoantenna structure 108 can be improved. This makes it possible to suppress characteristic variations of the metallic nanoantenna structure 108.

Note that, in the present modified example, in order to suppress light leakage between adjacent pixels, a film thickness of the planarization film 2201 is preferably the film thickness equal to or less than a target wavelength.

### 2.3.3 Third Modified Example

FIG. 31 is a cross-sectional view illustrating a schematic configuration example of a microsemiconductor light-emitting element according to a third modified example. As illustrated in FIG. 31, a microsemiconductor light-emitting element 2300 according to the third modified example has a configuration in which the reflector 109 is replaced with a reflector 109D that penetrates the planarization film 2201, the quantum dot layer 2101, and the passivation layer 107 and reaches the element forming surface of the substrate 101 in the same configuration as the microsemiconductor light-emitting element 2200 described above with reference to FIG. 30.

As described above, by providing the reflector 109D on a side surface of the planarization film 2201 in addition to the quantum dot layer 2101, leakage light to the adjacent pixels is reduced by the light leakage prevention effect. Therefore, the light utilization efficiency can be further improved to suppress reduction of luminance.

Note that, in the present modified example, leakage of light between adjacent pixels can be suppressed without setting the film thickness of the planarization film 2201 to the film thickness equal to or less than the target wavelength.

### 3. Third Embodiment

In a third embodiment, a display device using the semiconductor light-emitting element according to the above-described embodiment will be described.

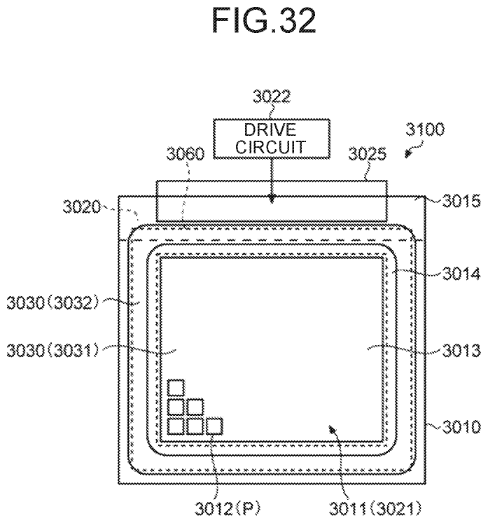

FIG. 32 is a schematic diagram illustrating a configuration example of the display device according to the third embodiment. A display device 3100 is an organic EL display that drives an organic EL element to display an image.

The display device 3100 is configured as, for example, a display module, and is equipped in various electronic apparatuses as a viewfinder such as a video camera or a digital camera, or a display such as a smartphone or a tablet. Types and the like of the electronic apparatus in which the display device 3100 is used are not limited, and the present technology is also applicable to, for example, a case where the display device is used as a monitor for a television or a PC.

FIG. 32 schematically illustrates a plan view of the display device 3100 viewed from a side on which an image is displayed, i.e., a side from which light of the organic EL element is emitted. The display device 3100 includes an element substrate 3010, a transparent substrate 3020 disposed on the element substrate 3010, and a color filter layer 3030. In the display device 3100, an image is displayed through the transparent substrate 3020.

The element substrate 3010 has a first facing surface 3011 facing the transparent substrate 3020, a plurality of organic EL elements 3012, and a peripheral wiring 3060. The plurality of organic EL elements 3012 constitutes a plurality of pixels P configuring an image. FIG. 32 schematically illustrates a square pixel P. The number of pixels, the pixel size, and the like in the display device 3100 are not limited, and may be appropriately set so that a desired resolution and the like can be realized. In the present embodiment, the first facing surface 3011 corresponds to a first surface.

The first facing surface 3011 is provided with a display region 3013, a peripheral region 3014, and an external region 3015. The display region 3013 is a rectangular region in which the plurality of pixels P is arranged, and is a region in which an image is actually displayed. In the present embodiment, light is emitted from the display region 3013 of the first facing surface 3011 by the organic EL elements 3012 to display the image. Therefore, the display region 3013 is an area including an effective pixel area in which the pixels P contributing to actual image display are arranged.

The peripheral region 3014 is a region surrounding the display region 3013. In other words, the peripheral region 3014 is an area surrounding the image displayed on the display device 3100, and a width of a bezel (frame) of the display device 3100 is determined, for example, by a width of the peripheral region 3014. In the example illustrated in FIG. 32, the peripheral region 3014 is a region of the first facing surface 3011 excluding the display region 3013 and the external region 3015 arranged outside the display region 3013 and spaced apart from the display region 3013.

The external region 3015 is provided outside the peripheral region 3014 in the first facing surface 3011, and is a region (upper side in FIG. 32) where the transparent substrate 3020 is not disposed and the element substrate 3010 (first facing surface 3011) is exposed. An external electrode 3025 is provided in the external region 3015. A drive circuit 3022 that drives the display device 3100 is connected to the external electrode 3025 via a flexible substrate or the like. The drive circuit 3022 is mounted on a main body of the electronic apparatus to supply power for driving the organic EL elements 3012, image signals, and the like to the display device 3100. Types of the drive circuit 3022 or the drive signal are not limited.

The peripheral wiring 3060 is disposed so as to overlap the peripheral region 3014 surrounding the display region 3013 in plan view. In the present description, the plan view is, for example, a state viewed from a direction (normal direction) perpendicular to the surface of the transparent substrate 3020 on a side on which an image is displayed on the display device 3100. Therefore, the peripheral wiring 3060 is arranged on a layer below the peripheral region 3014 so as to be accommodated in the peripheral region 3014 when viewed from the transparent substrate 3020. In FIG. 32, the peripheral wiring 3060 is schematically illustrated by a dotted line region.

The peripheral wiring 3060 includes various wirings and circuits for driving the organic EL elements 3012. Specifically, the peripheral wiring 3060 includes a plurality of conductive films (metal films, transparent conductive films, and the like), transistors, capacitive elements, and the like formed in layers on the element substrate 3010. The peripheral wiring 3060 is appropriately connected to the external electrode 3025 and each organic EL element 3012 described above. A specific configuration of the peripheral wiring 3060 will be described in detail later.

The transparent substrate 3020 protects the organic EL elements 3012 and the like formed on the element substrate 3010. The transparent substrate 3020 has a second facing surface 3021 facing the first facing surface 3011. The transparent substrate 3020 is disposed with the second facing surface 3021 facing the first facing surface 3011 of the element substrate 3010 so as to cover the display region 3013 and the peripheral region 3014. As the transparent substrate 3020, for example, any substrate having transparency such as a glass substrate, a silicon oxide substrate, or an acrylic substrate may be used.

The color filter layer 3030 includes a color filter that transmits light having a predetermined wavelength. The color filter layer 3030 includes a plurality of color filters that transmit light of different wavelengths. The color filter layer 3030 is disposed between the element substrate 3010 and the transparent substrate 3020 so as to overlap the display region 3013 and the peripheral region 3014 in plan view.

In the present embodiment, a colored filter unit 3031 is configured by the color filters arranged so as to overlap the display region 3013 in plan view. Furthermore, a light shielding filter unit 3032 is configured by the color filters arranged to overlap the peripheral region 3014 in plan view. In FIG. 32, the colored filter unit 3031 overlapping the display region 3013 is illustrated as a dark gray area, and the light shielding filter unit 3032 overlapping the peripheral region 3014 is illustrated as a light gray area. The colored filter unit 3031 and the light shielding filter unit 3032 will be described in detail later.

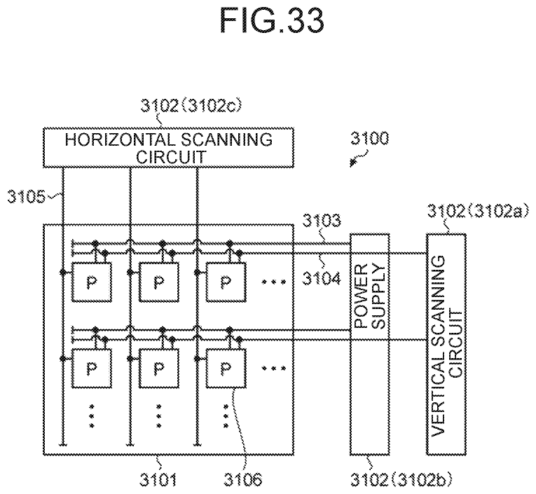

Here, a circuit configuration of the display device 3100 will be described. FIG. 33 is a block diagram illustrating an overall configuration example of the display device 3100. The display device 3100 includes a pixel array 3101 including the plurality of pixels P, and a drive unit 3102 that drives the pixel array 3101. The pixel array 3101 is provided on the element substrate 3010 so as to overlap the display region 3013 illustrated in FIG. 32, and the drive unit 3102 is provided on the element substrate 3010 so as to overlap the peripheral region 3014.

The pixel array 3101 includes the plurality of pixels P arranged in a matrix and a power supply line 3103 arranged corresponding to each row of the plurality of pixels P. Each of the pixels P includes a pixel circuit 3106 arranged at a portion where a scanning line 3104 in a row and a signal line 3105 in a column intersect.

The drive unit 3102 includes a vertical scanning circuit 3102a, a power supply 3102b, and a horizontal scanning circuit 3102c. The vertical scanning circuit 3102a sequentially supplies a control signal to each scanning line 3104 to sequentially scan pixels P row by row. The power supply 3102b supplies a constant power supply potential to each power supply line 3103 to drive the pixel circuit 3106 configuring the pixel P. Constant power supply potential can simplify a configuration of the power supply 3102b, and reduce an element size. The horizontal scanning circuit 3102c supplies a signal potential for an image signal (video signal) and a reference potential to each signal line 3105 according to scanning of the vertical scanning circuit 3102a.

A specific configuration of the drive unit 3102 is not limited. For example, as the power supply 3102b, a power supply scanner or the like may be used to supply a power supply potential that switches each power supply line 3103 between high potential and low potential according to scanning of the vertical scanning circuit 3102a. As a result, for example, even when the display device 3100 is mounted on a medium electronic apparatus (smartphone or the like) or a large electronic apparatus (television, PC monitor, or the like), it is possible to stably drive the display device 3100 while suppressing power consumption.

### 4. Fourth Embodiment

In a fourth embodiment, an application example of the display device according to the above-described third embodiment will be described.

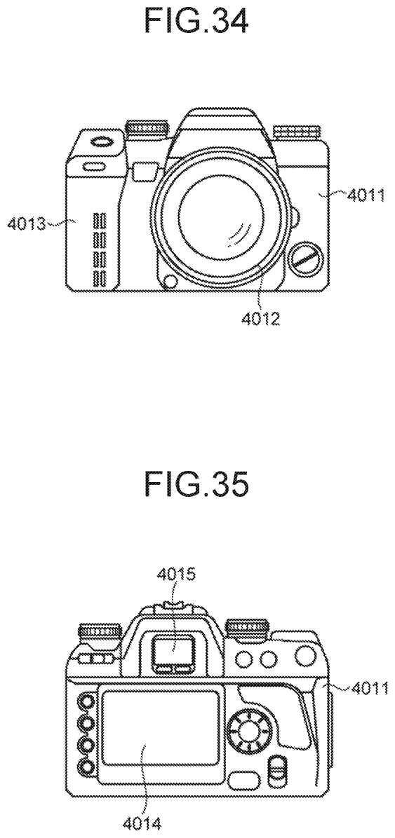

The display device according to the third embodiment described above can be applied to, for example, a lens interchangeable mirrorless type digital still camera. FIG. 34 is a front view and FIG. 35 is a rear view of the digital still camera. This lens interchangeable mirrorless type digital still camera includes, for example, an interchangeable imaging lens unit (interchangeable lens) 212 on a front right side of a camera body 4011, and a grip 4013 to be held by a photographer on a front left side. A monitor device 4014 is provided substantially at a center of a back surface of the camera body 4011. An electronic viewfinder (eyepiece window) 4015 is provided above the monitor device 4014. By looking into the electronic viewfinder 4015, the photographer can determine the composition by visually recognizing an optical image of a subject guided by an imaging lens unit 4012. In the lens interchangeable mirrorless type digital still camera having this configuration, the display device according to the third embodiment described above can be used as the electronic viewfinder 4015.

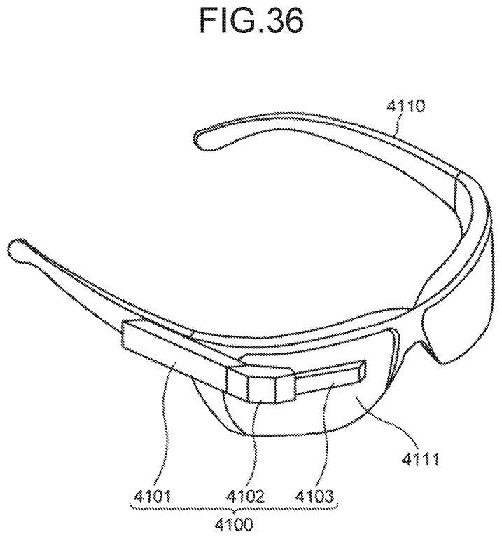

Alternatively, the display device according to the third embodiment described above can be applied to, for example, a head mounted display. As illustrated in an external view in FIG. 36, a head mounted display 4100 includes a transmissive head mounted display including a main body 4101, an arm 4102, and a lens barrel 4103. The main body 4101 is connected to the arm 4102 and eyeglasses 4110. Specifically, an end of the main body 4101 in a long side direction is attached to the arm 4102. One side of a side surface of the main body 4101 is connected to the eyeglasses 4110 via a connector (not illustrated). Note that the main body 4101 may be directly mounted on a head of human body. The main body 4101 includes a built-in control board and a built-in display unit for controlling the operation of the head mounted display 4100. The arm 4102 supports the lens barrel 4103 with respect to the main body 4101 by connecting the main body 4101 and the lens barrel 4103. Specifically, the arm 4102 is coupled to the end of the main body 4101 and an end of the lens barrel 4103 to fix the lens barrel 4103 to the main body 4101. Furthermore, the arm 4102 incorporates a signal line for communicating data related to an image provided from the main body 4101 to the lens barrel 4103. The lens barrel 4103 projects image light provided from the main body 4101 via the arm 4102 toward eyes of a user wearing the head mounted display 4100 through a lens 4111 of the eyeglasses 4110. In the head mounted display 4100 having the above-described configuration, the display device according to the above-described third embodiment can be used as the display unit built in the main body 4101.

The technical scope of the present disclosure is not limited to the above-described embodiment, and various modifications can be made without departing from the gist of the present disclosure. In addition, the components of different embodiments and modifications may be appropriately combined.

Note that the effects of each embodiment described in the present specification are merely examples and not limited thereto, and other effects may be provided.

The present technology can also have the following configurations.

(1)

A semiconductor device including:
a light emitter provided on an upper surface of a substrate;
a microstructure made of metal disposed on a side opposite to the substrate with the light emitter interposed between the microstructure and the substrate, the microstructure being spaced apart from the light emitter by a predetermined distance; and
a reflector provided on the substrate, the reflector partitioning the semiconductor device and an adjacent semiconductor device.
   (2)

The semiconductor device according to (1), wherein
the predetermined distance is ¼ or more of a wavelength of light re-emitted from the microstructure.
   (3)

The semiconductor device according to (1) or (2), wherein
at least a surface of the reflector contains metal.
   (4)

The semiconductor device according to any one of (1) to (3), wherein
the reflector has a tapered shape whose cross-sectional area decreases as being away from the substrate or a reverse tapered shape whose cross-sectional area increases as being away from the substrate.
   (5)

The semiconductor device according to any one of (1) to (4), wherein
a lower end of the reflector at least reaches the upper surface of the substrate.
   (6)

The semiconductor device according to any one of (1) to (5), wherein
a distance from an upper end of the reflector to a lower end of the microstructure in a direction perpendicular to the upper surface of the substrate is equal to or more than a wavelength of light re-emitted from the microstructure.
   (7)

The semiconductor device according to any one of (1) to (6), further including:
a first insulating film provided on the upper surface of the substrate, the first insulating film covering the light emitter, wherein
the microstructure is located on an upper surface of the first insulating film.
   (8)

The semiconductor device according to any one of (1) to (6), further including:
a first insulating film provided on the upper surface of the substrate, the first insulating film covering the light emitter, wherein
the microstructure is located in the first insulating film.
   (9)

The semiconductor device according to any one of (1) to (8), wherein
the light emitter includes:
a lower electrode provided on the upper surface of the substrate;
a photoelectric converter provided on the lower electrode; and
an upper electrode provided on a side opposite to the lower electrode with the photoelectric converter interposed between the lower electrode and the upper electrode.
   (10)

The semiconductor device according to (9), wherein
the photoelectric converter is an organic film.
   (11)

The semiconductor device according to (9) or (10), wherein
the reflector is electrically connected to the lower electrode.
   (12)

The semiconductor device according to any one of (1) to (11), wherein
the microstructure includes a plurality of columnar structures arranged on a surface parallel to the upper surface of the substrate.
   (13)

The semiconductor device according to (12), wherein
a cross-sectional shape of each of the columnar structures is any one of a circular shape, an elliptical shape, and a polygonal shape.
   (14)

The semiconductor device according to (12) or (13), wherein
an edge on an upper surface side of each of the columnar structures is rounded.
   (15)

The semiconductor device according to any one of (12) to (14), wherein
the microstructure includes at least two types of the columnar structures having different sizes arranged in a predetermined periodic array.
   (16)

The semiconductor device according to any one of (12) to (15), wherein
the columnar structures are arranged in a first direction and a second direction perpendicular to the first direction, and
a period of the columnar structures in the first direction is different from a period of the columnar structures in the second direction.
   (17)

The semiconductor device according to any one of (12) to (16), wherein
an interval between the columnar structures adjacent to each other is different between near a center and near an outer periphery in a region where the microstructure is arranged.
   (18)

The semiconductor device according to any one of (1) to (17), wherein
the semiconductor device is a pixel having a reduced element area.
   (19)

The semiconductor device according to (18), wherein
a size of the semiconductor device in a direction parallel to an element forming surface of the substrate is 20 μm or less.
   (20)

A display device including:
a pixel array unit in which the semiconductor device according to any one of (1) to (19) is arranged in a matrix; and
a drive circuit that drives the semiconductor device.

### REFERENCE SIGNS LIST

100, 100A, 200, 300, 400, 500, 600, 700, 800, 1100 SEMICONDUCTOR LIGHT EMITTING ELEMENT
101 SUBSTRATE
102 LOWER ELECTRODE
103 ORGANIC LAYER
104 UPPER ELECTRODE
105 LIGHT EMITTER
106 INSULATOR
107 PASSIVATION LAYER
108, 1108 METALLIC NANOANTENNA STRUCTURE
108a to 108h COLUMNAR STRUCTURE
109, 109A, 109B, 109C, 109D, 209, 309, 409, 509, 609, 709 REFLECTOR
110, 2201 PLANARIZATION FILM
111 COLOR FILTER
112 ON-CHIP LENS
609a REFLECTIVE FILM
609b INSULATING LAYER
1108a CENTRAL PORTION
1108b PERIPHERAL PORTION
2000, 2100, 2200, 2300 MICROSEMICONDUCTOR LIGHT-EMITTING ELEMENT
2101 QUANTUM DOT LAYER
3022 DRIVE CIRCUIT
3100 DISPLAY DEVICE
3101 PIXEL ARRAY

1. A semiconductor device including:
a light emitter provided on an upper surface of a substrate;
a microstructure made of metal disposed on a side opposite to the substrate with the light emitter interposed between the microstructure and the substrate, the microstructure being spaced apart from the light emitter by a predetermined distance; and
a reflector provided on the substrate, the reflector partitioning the semiconductor device and an adjacent semiconductor device.

2. The semiconductor device according to claim 1, wherein
the predetermined distance is ¼ or more of a wavelength of light re-emitted from the microstructure.

3. The semiconductor device according to claim 1, wherein
at least a surface of the reflector contains metal.

4. The semiconductor device according to claim 1, wherein
the reflector has a tapered shape whose cross-sectional area decreases as being away from the substrate or a reverse tapered shape whose cross-sectional area increases as being away from the substrate.

5. The semiconductor device according to claim 1, wherein
a lower end of the reflector at least reaches the upper surface of the substrate.

6. The semiconductor device according to claim 1, wherein
a distance from an upper end of the reflector to a lower end of the microstructure in a direction perpendicular to the upper surface of the substrate is equal to or more than a wavelength of light re-emitted from the microstructure.

7. The semiconductor device according to claim 1, further including:
a first insulating film provided on the upper surface of the substrate, the first insulating film covering the light emitter, wherein
the microstructure is located on an upper surface of the first insulating film.

8. The semiconductor device according to claim 1, further including:
a first insulating film provided on the upper surface of the substrate, the first insulating film covering the light emitter, wherein
the microstructure is located in the first insulating film.

9. The semiconductor device according to claim 1, wherein the light emitter includes:
a lower electrode provided on the upper surface of the substrate;
a photoelectric converter provided on the lower electrode; and
an upper electrode provided on a side opposite to the lower electrode with the photoelectric converter interposed between the lower electrode and the upper electrode.

10. The semiconductor device according to claim 9, wherein
the photoelectric converter is an organic film.

11. The semiconductor device according to claim 9, wherein
the reflector is electrically connected to the lower electrode.

12. The semiconductor device according to claim 1, wherein
the microstructure includes a plurality of columnar structures arranged on a surface parallel to the upper surface of the substrate.

13. The semiconductor device according to claim 12, wherein
a cross-sectional shape of each of the columnar structures is any one of a circular shape, an elliptical shape, and a polygonal shape.

14. The semiconductor device according to claim 12, wherein
an edge on an upper surface side of each of the columnar structures is rounded.

15. The semiconductor device according to claim 12, wherein
the microstructure includes at least two types of the columnar structures having different sizes arranged in a predetermined periodic array.

16. The semiconductor device according to claim 12, wherein
the columnar structures are arranged in a first direction and a second direction perpendicular to the first direction, and
a period of the columnar structures in the first direction is different from a period of the columnar structures in the second direction.

17. The semiconductor device according to claim 12, wherein
an interval between the columnar structures adjacent to each other is different between near a center and near an outer periphery in a region where the microstructure is arranged.

18. The semiconductor device according to claim 1, wherein
the semiconductor device is a pixel having a reduced element area.

19. The semiconductor device according to claim 18, wherein
a size of the semiconductor device in a direction parallel to an element forming surface of the substrate is 20 μm or less.

20. A display device including:
a pixel array unit in which the semiconductor device according to claim 1 is arranged in a matrix; and
a drive circuit that drives the semiconductor device.
